(19) United States
(12) Patent Application Publication
(10) Pub. No.: US 2015/0115309 A1
(43) Pub. Date: Apr. 30, 2015

(54) LIGHT EMITTING DIODE STRUCTURE

(71) Applicant: Lextar Electronics Corporation, Hsinchu (TW)

(72) Inventors: Nai-Wei HSU, Tainan City (TW); Te-Chung WANG, Taichung City (TW); Tzong-Liang TSAI, Taichung City (TW)

(21) Appl. No.: 14/493,478

(22) Filed: Sep. 23, 2014

(30) Foreign Application Priority Data
Oct. 24, 2013 (TW) 102138494

(51) Int. Cl. H01L 33/62; H01L 33/44; H01L 33/36

(52) U.S. Cl. CPC H01L 33/62; H01L 33/36; H01L 33/44
USPC 257/99

(57) ABSTRACT

A light emitting diode structure includes a substrate, an N-type semiconductor layer, a light emitting layer, a P-type semiconductor layer, a composite conductive layer, a first electrode, and a second electrode. The N-type semiconductor layer is located on the substrate. The light emitting layer is located on a portion of the N-type semiconductor layer. The P-type semiconductor layer is located on the light emitting layer. The composite conductive layer sequentially has a first conductive layer, a second conductive layer, and a third conductive layer. The first conductive layer is attached to the P-type semiconductor layer, and the resistance of the first conductive layer is greater than the resistance of the third conductive layer. The first electrode is located on the third conductive layer. The second electrode is located on another portion of the N-type semiconductor layer that is not covered by the light emitting layer.

### RELATED APPLICATIONS

This application claims priority to Taiwan Application Ser. No. 102138494, filed Oct. 24, 2013, which is herein incorporated by reference.

### BACKGROUND

1. Field of Invention

The present invention relates to a light emitting diode structure.

2. Description of Related Art

A conventional light emitting diode element is composed of a sapphire substrate, and an epitaxial layer (e.g., an N—GaN layer, a light emitting layer, and a P—GaN layer), a transparent conductive layer, and a conductive pad formed on the sapphire substrate.

Since the impedance of the P—GaN layer is very large, a current has to horizontally flow through the transparent conductive layer. If the transparent conductive layer has a poor transmittance and overly high impedance, a large portion of the current directly vertically flows from a positive electrode on the transparent conductive layer to the N—GaN layer passing through the transparent conductive layer and the P—GaN layer; thereafter, the current flows in a horizontal direction through the N—GaN layer. As a result, a current crowding problem occurs at a positive electrode side of the light emitting diode element, which causes more difficulty to improve the light emitting efficiency of the light emitting diode element and to reduce the operating voltage of the light emitting diode element.

Moreover, when most of the current has difficulty to horizontally flow through the transparent conductive layer, significant heat formed by the light emitting diode element is going to accumulate at the positive electrode on the transparent conductive layer. In order to improve the heat dissipation rate of the light emitting diode element, designers can arrange a pad finger electrically connected to the positive electrode, such that the current can flow in a horizontal direction through the pad finger. However, the pad finger which is opaque decreases the light emitting area of the light emitting diode element, and makes the improvement of the brightness of the light emitting diode element even difficult.

### SUMMARY

An aspect of the present invention is to provide a light emitting diode structure.

According to an embodiment of the present invention, a light emitting diode structure includes a substrate, an N-type semiconductor layer, a light emitting layer, a P-type semiconductor layer, a composite conductive layer, a first electrode, and a second electrode. The N-type semiconductor layer is located on the substrate. The light emitting layer is located on a portion of the N-type semiconductor layer. The P-type semiconductor layer is located on the light emitting layer. The composite conductive layer sequentially has a first conductive layer, a second conductive layer, and a third conductive layer. The first conductive layer is attached to the P-type semiconductor layer, and the resistance of the first conductive layer is greater than the resistance of the third conductive layer. The first electrode is located on the third conductive layer. The second electrode is located on another portion of the N-type semiconductor layer that is not covered by the light emitting layer.

In an embodiment of the present invention, the second conductive layer has a concave-convex surface or a discontinuous surface.

In an embodiment of the present invention, the first, second, and third conductive layers are made of a material that includes a transparent conductive oxide.

In an embodiment of the present invention, the transparent conductive oxide is selected from the group consisting of indium tin oxide, aluminum zinc oxide, and zinc oxide.

In an embodiment of the present invention, a surface roughness of the second conductive layer is greater than a surface roughness of the first conductive layer and a surface roughness of the third conductive layer.

In an embodiment of the present invention, the first conductive layer is made of a material that includes nickel, gold, or nickel gold alloy, and a thickness of the first conductive layer is smaller than 30 Å.

In an embodiment of the present invention, the second conductive layer is made of a material that includes graphene, a plurality of silicon spacers, a plurality of nickel spacers, or a plurality of silver particles.

In an embodiment of the present invention, the third conductive layer is made of a material that includes aluminum, titanium, chromium, nickel, or alloy thereof, and a thickness of the third conductive layer is smaller than 30 Å.

In the aforementioned embodiments of the present invention, the composite conductive layer of the light emitting diode structure has the first, second, and third conductive layers that are stacked in sequence, and the resistance of the first conductive layer is greater than the resistance of the third conductive layer. Therefore, when the first and second electrodes of the light emitting diode structure receive a power, a current can effectively flow in a horizontal direction by utilizing the third conductive layer. As a result, a current crowding problem happened adjacent to the first electrode side of the light emitting diode structure may be prevented, such that the light emitting efficiency of the light emitting diode structure may be improved, and the operating voltage of the light emitting diode structure may be reduced.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a top view of a light emitting diode structure according to an embodiment of the present invention;

FIG. 2A is a cross-sectional view taken along line 2-2 of the light emitting diode structure shown in FIG. 1;

FIG. 2B is a partial enlarged view of a composite conductive layer shown in FIG. 2A;

FIG. 3 is a schematic view of a current path between a first electrode and a second electrode shown in FIG. 2A when the first and second electrodes receive a power; and

FIG. 4 is a cross-sectional view of a light emitting diode structure according to another embodiment of the present invention, and the cross-sectional position is the same as FIG. 2A.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

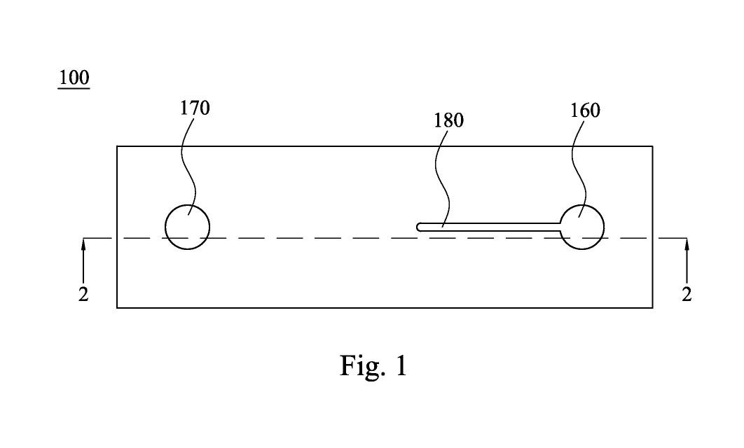

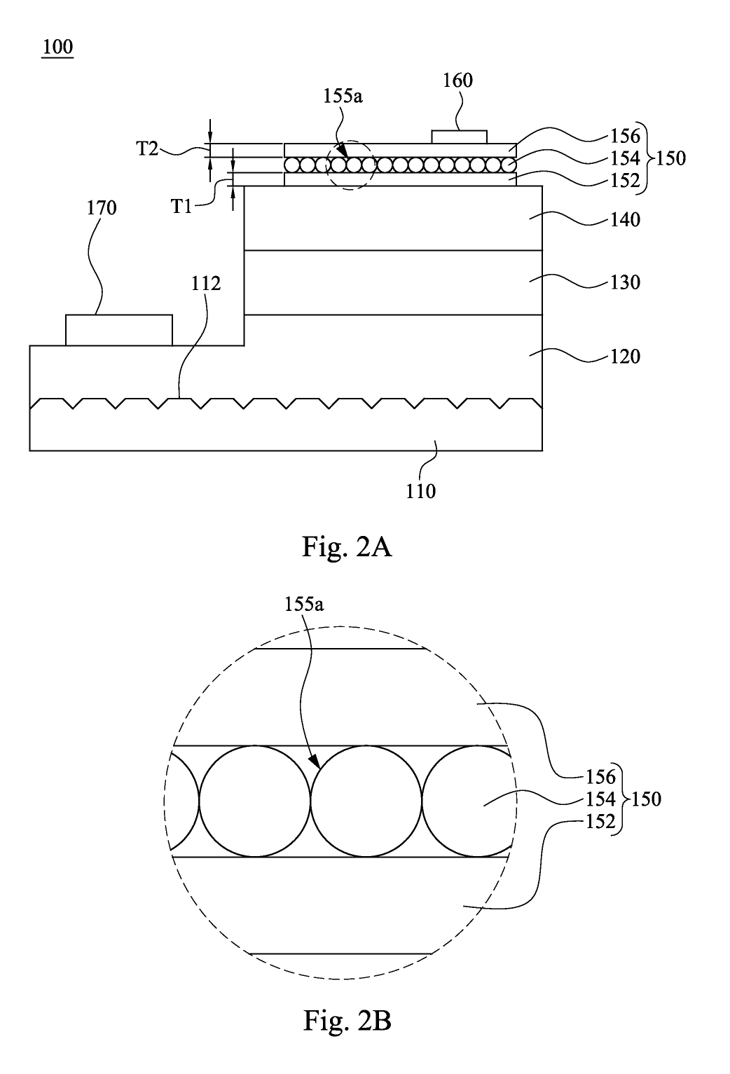

FIG. 1 is a top view of a light emitting diode structure 100 according to an embodiment of the present invention. FIG. 2A is a cross-sectional view taken along line 2-2 of the light emitting diode structure 100 shown in FIG. 1. As shown in FIG. 1 and FIG. 2A, the light emitting diode structure 100 includes a substrate 110, an N-type semiconductor layer 120, a light emitting layer 130, a P-type semiconductor layer 140, a composite conductive layer 150, a first electrode 160, and a second electrode 170. The N-type semiconductor layer 120 is located on the substrate 110. The light emitting layer 130 is located on a portion of the N-type semiconductor layer 120. The P-type semiconductor layer 140 is located on the light emitting layer 130. The composite conductive layer 150 sequentially has a first conductive layer 152, a second conductive layer 154, and a third conductive layer 156. The first, second, and third conductive layers 152, 154, 156 are stacked in sequence. The first conductive layer 152 is attached to the P-type semiconductor layer 140, and the resistance of the first conductive layer 152 is greater than the resistance of the third conductive layer 156. The first electrode 160 is located on the third conductive layer 156. The second electrode 170 is located on another portion of the N-type semiconductor layer 120 that is not covered by the light emitting layer 130.

The substrate 110 may be, but not limited to a sapphire substrate having a concave-convex structure 112. When the light emitting layer 130 emits light, the light may be refracted or reflected by the concave-convex structure 112. Moreover, the N-type semiconductor layer 120 and the P-type semiconductor layer 140 may be made of a material that includes nitride, such as the N-type semiconductor layer 120 may be N—GaN, and the P-type semiconductor layer 140 may be P—GaN, but the present invention is not limited in this regard.

FIG. 2B is a partial enlarged view of the composite conductive layer 150 shown in FIG. 2A. As shown in FIG. 2A and FIG. 2B, in this embodiment, the surface roughness of the second conductive layer 154 is greater than the surface roughness of the first conductive layer 152 and the surface roughness of the third conductive layer 156. The first conductive layer 152 may be made of a material that comprises nickel, gold, or nickel gold alloy, and the thickness T1 of the first conductive layer 152 is smaller than 30 Å. The second conductive layer 154 may be made of a material that includes graphene, a plurality of silicon spacers, a plurality of nickel spacers, or a plurality of silver particles, such that the second conductive layer 154 has a discontinuous surface 155a. The third conductive layer 156 may be made of a material that includes aluminum, titanium, chromium, nickel, or alloy thereof, and the thickness T2 of the third conductive layer 156 is smaller than 30 Å.

In the following description, the flow status of the current in the light emitting diode structure 100 will be described.

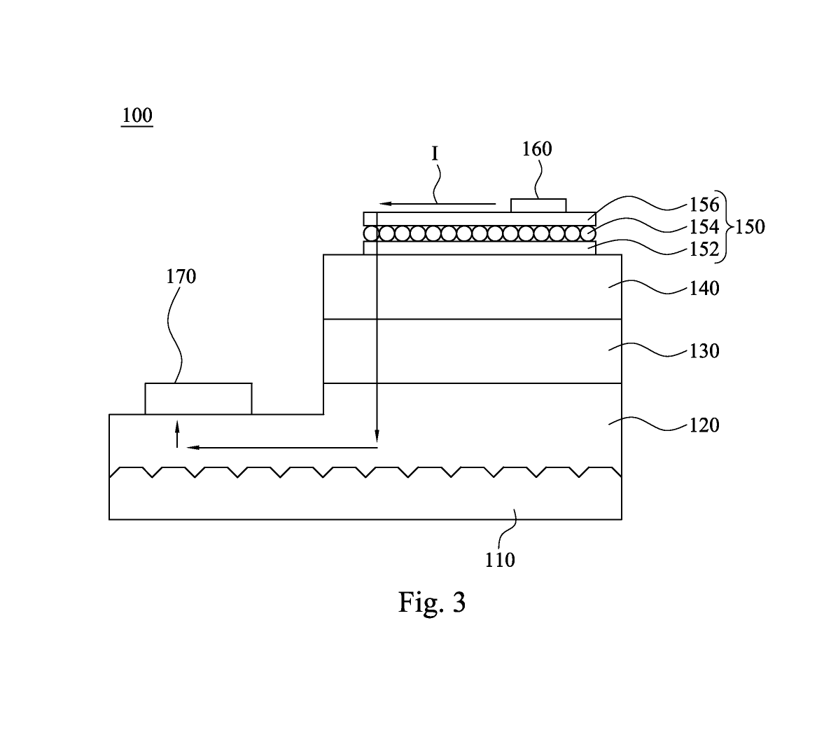

FIG. 3 is a schematic view of a current path I between the first electrode 160 and the second electrode 170 shown in FIG. 2A when the first and second electrodes 160, 170 receive a power. As shown in FIG. 3, since the composite conductive layer 150 of the light emitting diode structure 100 has the first, second, and third conductive layers 152, 154, 156 that are stacked in sequence, and the resistance of the first conductive layer 152 is greater than the resistance of the third conductive layer 156, the first conductive layer 152 attached to the P-type semiconductor layer 140 can prevent the current directly flowing in a vertical direction from the first electrode 160, and the third conductive layer 156 can effectively and horizontally conduct the current. As a result, a current crowding problem happened adjacent to the side of the first electrode 160 of the light emitting diode structure 100 may be prevented, such that the light emitting efficiency of the light emitting diode structure 100 may be improved, and the operating voltage of the light emitting diode structure 100 may be reduced.

Furthermore, when a large portion of the current can flow in a horizontal direction by utilizing the composite conductive layer 150, heat generated by the light emitting diode structure 100 is uniformly distributed, thereby improving the heat dissipation efficiency. That is to say, a finger electrode 180 (see FIG. 1) electrically connected to the first electrode 160 does not need to have a large area or quantity to conduct the current in a horizontal direction for the heat dissipation of the light emitting diode structure 100. As a result, the area of the finger electrode 180 of the light emitting diode structure 100 may be decreased, such that the light emitting area of the light emitting diode structure 100 may be increased to improve the brightness of the light emitting diode structure 100. Moreover, the layout design of the finger electrode 180 may also be more flexible.

As shown in FIG. 2B and FIG. 3, the surface roughness of the second conductive layer 154 having the discontinuous surface 155a is greater than the surface roughness of the first conductive layer 152 and the surface roughness of the third conductive layer 156. Therefore, when the light emitting layer 130 emits light, the second conductive layer 154 can refract or reflect the light to decrease the light absorption of the second conductive layer 154, such that the light extraction probability of the light emitting diode structure 100 is increased to improve the brightness.

It is to be noted that the connection relationships and the materials of the elements described above will not be repeated in the following description. In the following description, other types of the composite conductive layer 150 will be described.

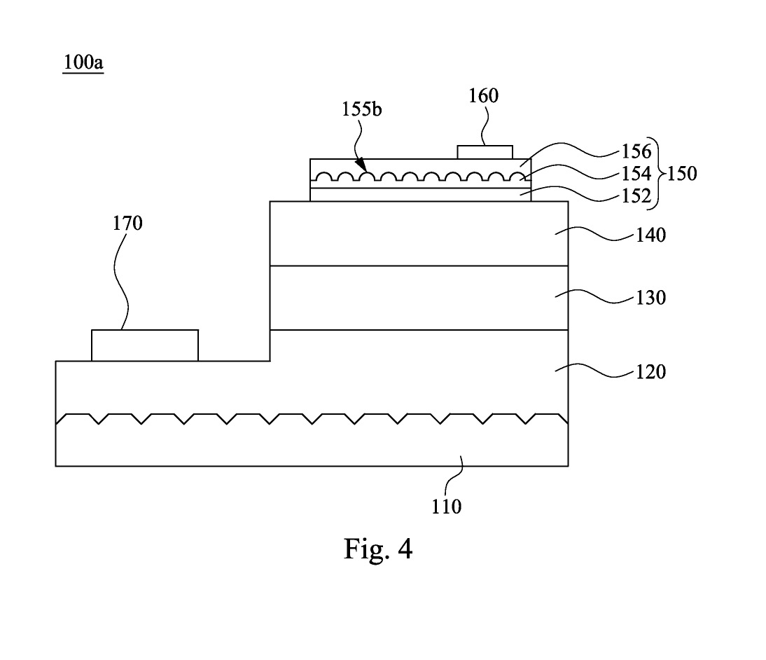

FIG. 4 is a cross-sectional view of a light emitting diode structure 100a according to another embodiment of the present invention, and the cross-sectional position is the same as FIG. 2A. As shown in FIG. 4, the light emitting diode structure 100a includes the substrate 110, the N-type semiconductor layer 120, the light emitting layer 130, the P-type semiconductor layer 140, the composite conductive layer 150, the first electrode 160, and the second electrode 170. The different between this embodiment and the embodiment shown in FIG. 2A is that the first, second, and third conductive layers 152, 154, 156 of the composite conductive layer 150 are made of a material that includes a transparent conductive oxide, and the second conductive layer 154 has a concave-convex surface 155b. The composite conductive layer 150 may be manufactured by the same material, thus causing convenience in manufacturing process. Moreover, the cost of manufacturing equipments may be reduced. The transparent conductive oxide may be selected from the group consisting of indium tin oxide (ITO), aluminum zinc oxide (AZO), and zinc oxide (ZnO), but the present invention is not limited in this regard.

When the composite conductive layer 150 is manufactured, the first conductive layer 152 attached to the P-type semiconductor layer 140 may be formed a high impedance conductive layer by adjusting parameters. RF generated by a film deposition equipment may easily damage the P-type semiconductor layer 140. Therefore, in parameter adjusting aspect, not only the flow rate of oxygen is adjusted, but also the flow field in the chamber of the film deposition equipment is adjusted to reduce the probability of carriers bombarding the surface of the P-type semiconductor layer 140.

The second conductive layer 154 may also be formed a rough surface by adjusting parameters. The continuous concave-convex surface 155b can destroy total reflection to increase the light extraction probability of the light emitting diode structure 100a to improve the brightness. When the rough second conductive layer 154 is formed, not only the flow rate of oxygen is adjusted, but also the RF power of the film deposition equipment is adjusted to increase more covering surface when the second conductive layer 154 forms the rough surface (i.e., the concave-convex surface 155b), and thereby preventing the surface from being discontinuous when the surface transforms to a rough surface.

For the desired low impedance of the third conductive layer 156 in contact with the first electrode 160, the RF power may be increased to increase the density of the third conductive layer 156 when the third conductive layer 156 is manufactured. Therefore, the impedance of the third conductive layer 156 may be reduced.

As a result, the current crowding problem happened adjacent to the side of the first electrode 160 of the light emitting diode structure 100a may be prevented, such that the light emitting efficiency of the light emitting diode structure 100a may be improved, and the operating voltage of the light emitting diode structure 100 may be reduced. Moreover, when a large portion of the current can flow in a horizontal direction by utilizing the composite conductive layer 150, heat generated by the light emitting diode structure 100a is uniformly distributed, thereby improving the heat dissipation efficiency.

In this embodiment, the surface roughness of the second conductive layer 154 having the concave-convex surface 155b is greater than the surface roughness of the first conductive layer 152 and the surface roughness of the third conductive layer 156. Therefore, when the light emitting layer 130 emits light, the second conductive layer 154 can refract or reflect the light, such that the light extraction probability of the light emitting diode structure 100a is increased to improve the brightness.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light emitting diode structure comprising:
a substrate;
an N-type semiconductor layer located on the substrate;
a light emitting layer located on a portion of the N-type semiconductor layer;
a P-type semiconductor layer located on the light emitting layer;
a composite conductive layer sequentially having a first conductive layer, a second conductive layer, and a third conductive layer, wherein the first conductive layer is attached to the P-type semiconductor layer, and a resistance of the first conductive layer is greater than a resistance of the third conductive layer;
a first electrode located on the third conductive layer; and
a second electrode located on another portion of the N-type semiconductor layer that is not covered by the light emitting layer.

2. The light emitting diode structure of claim 1, wherein the second conductive layer has a concave-convex surface or a discontinuous surface.

3. The light emitting diode structure of claim 1, wherein the first, second, and third conductive layers are made of a material that comprises a transparent conductive oxide.

4. The light emitting diode structure of claim 3, wherein the transparent conductive oxide is selected from the group consisting of indium tin oxide, aluminum zinc oxide, and zinc oxide.

5. The light emitting diode structure of claim 4, wherein a surface roughness of the second conductive layer is greater than a surface roughness of the first conductive layer and a surface roughness of the third conductive layer.

6. The light emitting diode structure of claim 1, wherein the first conductive layer is made of a material that comprises nickel, gold, or nickel gold alloy, and a thickness of the first conductive layer is smaller than 30 Å.

7. The light emitting diode structure of claim 6, wherein the second conductive layer is made of a material that comprises graphene, a plurality of silicon spacers, a plurality of nickel spacers, or a plurality of silver particles.

8. The light emitting diode structure of claim 7, wherein the third conductive layer is made of a material that comprises aluminum, titanium, chromium, nickel, or alloy thereof, and a thickness of the third conductive layer is smaller than 30 Å.
